(19) United States
(12) Patent Application Publication
(10) Pub. No.: US 2025/0226314 A1
(43) Pub. Date: Jul. 10, 2025

(54) SEMICONDUCTOR DEVICE AND SEMICONDUCTOR PACKAGE INCLUDING THE SAME

(71) Applicant: SAMSUNG ELECTRONICS CO., LTD., SUWON-SI (KR)

(72) Inventors: JEEWOONG KIM, Suwon-si (KR); YUNSUK NAM, Suwon-si (KR); HAEIN SHIN, Suwon-si (KR); SEBEOM OH, Suwon-si (KR); YONGWOO LEE, Suwon-si (KR); KEUN HWI CHO, Suwon-si (KR); HANBYUL CHOI, Suwon-si (KR)

(21) Appl. No.: 18/783,766

(22) Filed: Jul. 25, 2024

(30) Foreign Application Priority Data
Jan. 10, 2024 (KR) 10-2024-0003948

(51) Int. Cl. H01L 23/528; H01L 23/00; H01L 23/13; H01L 23/31; H01L 23/36; H01L 23/48; H01L 23/498; H01L 23/522; H01L 23/532; H01L 23/58; H01L 27/088; H01L 29/06; H01L 29/423; H01L 29/775; H01L 29/786

(52) U.S. Cl. CPC H01L 23/5283; H01L 23/13; H01L 23/585; H01L 24/16; H10D 84/83; H01L 23/3107; H01L 23/36; H01L 23/481; H01L 23/498; H01L 23/5228; H01L 23/5329; H01L 24/32; H01L 24/73; H01L 2224/16227; H01L 2224/32225; H01L 2224/73204; H10D 30/43; H10D 30/6735; H10D 30/6757; H10D 62/121

(57) ABSTRACT

A semiconductor device includes: an integrated circuit layer including a transistor; a first interconnection layer on a front side of the integrated circuit layer; a second interconnection layer on a back side of the integrated circuit layer; and a connection terminal on the second interconnection layer, wherein the second interconnection layer includes: an insulating layer; an interconnection structure in the insulating layer; an active contact disposed between the interconnection structure and a source/drain region of the transistor and connected to the source/drain region; and a dummy metal structure spaced apart from the interconnection structure in a first direction, and wherein the dummy metal structure does not overlap the connection terminal in a second direction that is perpendicular to the first direction.

### CROSS-REFERENCE TO RELATED APPLICATION

This U.S. non-provisional patent application claims priority under 35 U.S.C. § 119 to Korean Patent Application No. 10-2024-0003948 filed on Jan. 10, 2024, in the Korean Intellectual Property Office, the disclosure of which is incorporated by reference herein in its entirety.

### TECHNICAL FIELD

The inventive concept relates to a semiconductor device and a semiconductor package including the same.

### DISCUSSION OF RELATED ART

A back side thinning process has been introduced to address routing complexity at the back-end-of-line (BEOL) of one or more transistors, such as fin field-effect transistors (FinFETs) and nanosheet transistors, also known as multi-bridge channel field-effect transistors (MBCFETs).

This manufacturing process for semiconductor devices involving these transistors allows for the formation of one or more metal patterns for power delivery on the backside of the transistors, opposite to the BEOL side. These metal patterns, formed on the backside of the transistors, are referred to as a BSPDN or BSPDN structure, and the backside thinning process is referred to as the BSPDN process.

### SUMMARY

An embodiment of the inventive concept provides a semiconductor device with increased reliability by efficiently discharging heat generated in a transistor to its back side, and a semiconductor package including the same.

An embodiment of the inventive concept provides, a semiconductor device including: an integrated circuit layer including a transistor; a first interconnection layer on a front side of the integrated circuit layer; a second interconnection layer on a back side of the integrated circuit layer; and a connection terminal on the second interconnection layer, wherein the second interconnection layer includes: an insulating layer; an interconnection structure in the insulating layer; an active contact disposed between the interconnection structure and a source/drain region of the transistor and connected to the source/drain region; and a dummy metal structure spaced apart from the interconnection structure in a first direction, and wherein the dummy metal structure does not overlap the connection terminal in a second direction that is perpendicular to the first direction.

An embodiment of the inventive concept provides, a semiconductor package including: a package substrate; and a first semiconductor device on the package substrate, wherein the first semiconductor device includes: an integrated circuit layer including a transistor; a first interconnection layer on a front side of the integrated circuit layer; a second interconnection layer on a back side of the integrated circuit layer; and a connection terminal on the second interconnection layer, wherein the second interconnection layer includes: an insulating layer; an interconnection structure in the insulating layer; an active contact disposed between the interconnection structure and a source/drain region of the transistor and connected to the source/drain region; and a dummy metal structure spaced apart from the interconnection structure in a first direction, and wherein the dummy metal structure has a mesh shape when viewed in a plan view.

An embodiment of the inventive concept provides, a semiconductor device including: an integrated circuit layer including a transistor; a first interconnection layer on a front side of the integrated circuit layer; a second interconnection layer on a back side of the integrated circuit layer; and a connection terminal on the second interconnection layer, wherein the transistor includes: stacked channel patterns; a gate surrounding the channel patterns; and first and second source/drain regions spaced apart from each other with the channel patterns interposed therebetween, a first active contact protruding from the first interconnection layer and connected to the first source/drain region; and a second active contact protruding from the second interconnection layer and connected to the second source/drain region, wherein the second interconnection layer includes: an insulating layer including a first recess and a second recess at the bottom of the second interconnection layer; an interconnection structure in the insulating layer; and a dummy metal structure disposed in the insulating layer and spaced apart from the interconnection structure; an under bump pattern that fills the first recess and is disposed between the connection terminal and the insulating layer; and an insulating pattern that fills the second recess and is spaced apart from the under bump pattern in a first direction, and wherein the insulating layer and the insulating pattern include different insulating materials.

### BRIEF DESCRIPTION OF THE DRAWINGS

Example embodiments of the inventive concept will be more clearly understood from the following brief description taken in conjunction with the accompanying drawings. The accompanying drawings represent non-limiting, example embodiments as described herein.

FIG. 1 is a cross-sectional view of a semiconductor device according to some embodiments of the inventive concept.

FIG. 2 is an enlarged view of area ‘CU’ in FIG. 1.

FIG. 3 is a plan view showing a first region and a second region of the semiconductor device of FIG. 1.

FIGS. 4, 5, and 6 are enlarged views corresponding to area ‘CU’ in FIG. 1, respectively.

FIG. 7 is a cross-sectional view of a semiconductor package including a semiconductor device according to some embodiments of the inventive concept.

FIG. 8 is a cross-sectional view of a semiconductor package including a semiconductor device according to some embodiments of the inventive concept.

FIGS. 9, 10, and 11 are cross-sectional views showing a process of manufacturing a semiconductor device according to some embodiments of the inventive concept.

### DETAILED DESCRIPTION OF THE EMBODIMENTS

Hereinafter, a semiconductor device according to an embodiment the inventive concept will be described with reference to the drawings.

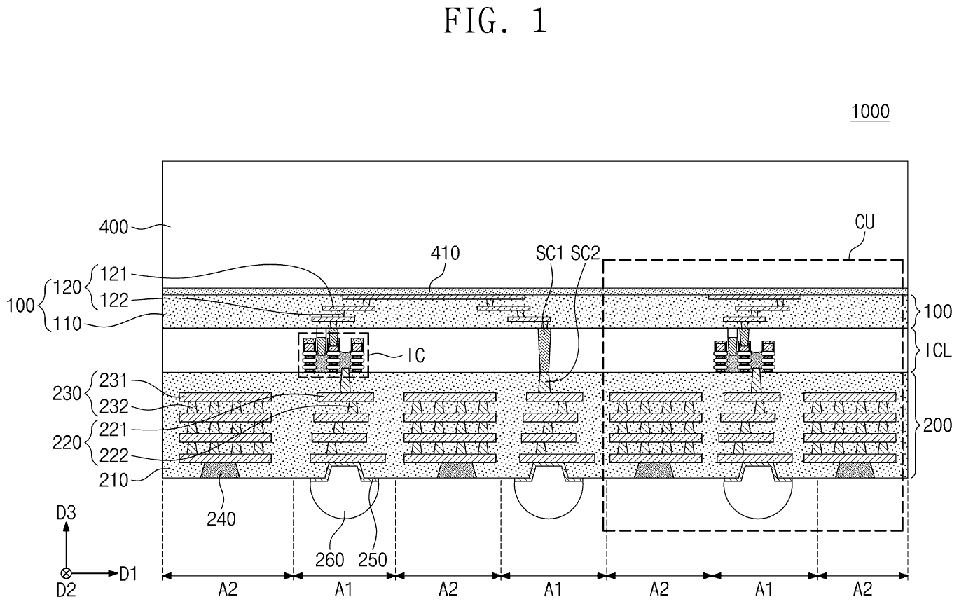

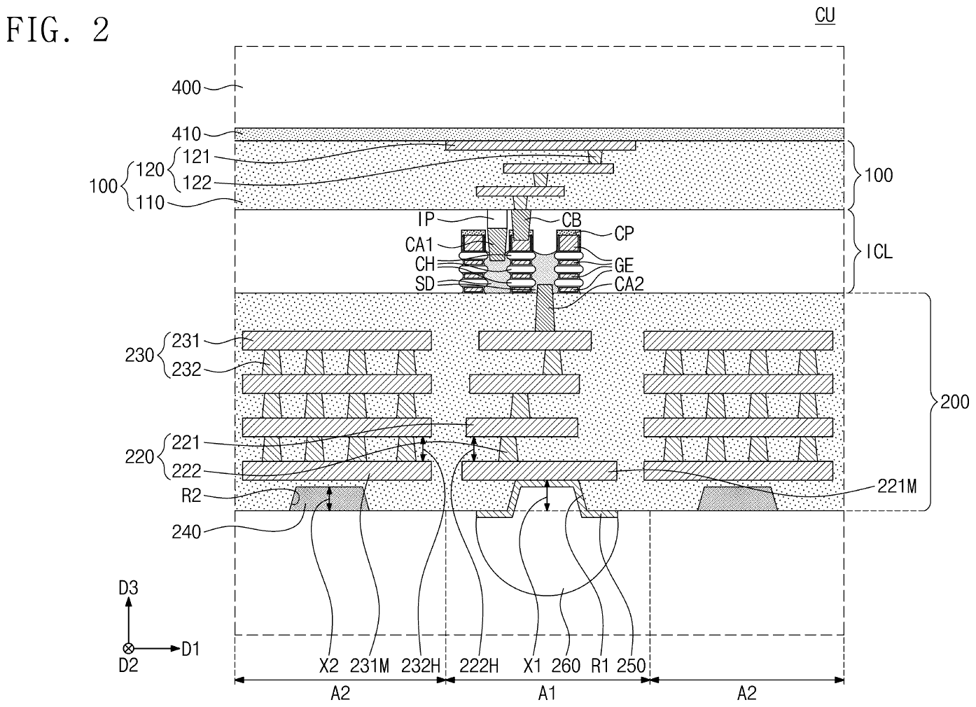

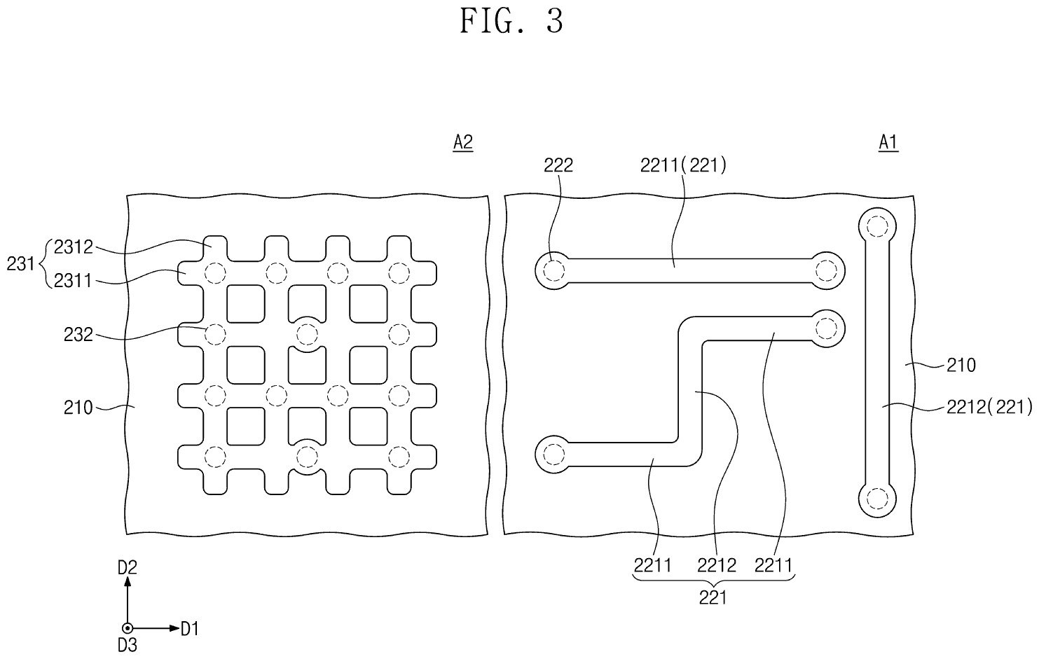

FIG. 1 is a cross-sectional view of a semiconductor device according to some embodiments of the inventive concept. FIG. 2 is an enlarged view of area ‘CU’ in FIG. 1. FIG. 3 is a plan view showing a first region and a second region of the semiconductor device of FIG. 1.

Referring to FIGS. 1 to 3, a semiconductor device 1000 may be, for example, a logic chip. In detail, the semiconductor device 1000 may be a logic chip such as an Application Specific Integrated Circuit (ASIC), a Central Processing Unit (CPU), a Graphic Processing Unit (GPU), and an Application Processor (AP).

The semiconductor device 1000 may include an integrated circuit layer ICL, a first interconnection layer 100, a second interconnection layer 200, a connection terminal 260, a support substrate 400, and an adhesive layer 410. The first interconnection layer 100 may also be referred to as a signal interconnection layer 100. The second interconnection layer 200 may also be referred to a power distribution interconnection layer 200.

The integrated circuit layer ICL may include an integrated circuit IC. The integrated circuit IC may include a transistor. The transistor may have a Gate All Around FET structure or a Multi Bridge Channel FET structure. The transistor may include channel patterns CH, gate GE, and source/drain patterns SD. The channel patterns CH may be stacked sequentially. The source/drain patterns SD may also be referred to as source/drain regions SD.

The gate GE may be disposed on the channel patterns CH, filling spaces between the channel patterns CH, and surrounding all sides of the channel patterns CH. The source/drain patterns SD may be spaced apart from each other with the channel patterns CH interposed therebetween. Each of the channel patterns CH and source/drain patterns SD may include a semiconductor material such as silicon (Si), germanium (Ge), or silicon-germanium (SiGe). A device isolation layer may be filled between integrated circuits IC. The device isolation layer may include an oxide, for example, silicon oxide (SiO₂).

A first active contact CA1 may be provided on one source/drain pattern SD of a pair of adjacent source/drain patterns SD, with the channel patterns CH disposed therebetween. Similarly, a second active contact CA2 may be provided on the other source/drain pattern SD. The first active contact CA1 may be referred to as a front side active contact CA1, while the second active contact CA2 may be referred to as a back side active contact CA2. The first active contact CA1 and the second active contact CA2 may be respectively connected to the source/drain patterns SD. A gate contact CB may be provided on the gate GE. The gate contact CB may be connected to the gate GE by penetrating a gate capping pattern CP that covers an upper surface of the gate GE. An upper portion of the first active contact CA1 adjacent to the gate contact CB may be filled with an upper insulating pattern IP.

In this specification, a first direction D1 is defined as a first direction D1 parallel to the upper surface of the channel pattern CH. A second direction D2 is defined as a direction parallel to the upper surface of the channel pattern CH and perpendicular to the first direction D1. A third direction D3 is defined as a direction perpendicular to the upper surface of the channel pattern CH.

The first interconnection layer 100 may be disposed on the front side of the integrated circuit layer ICL. The first interconnection layer 100 may include a first insulating layer 110 and first interconnection structures 120 disposed in the first insulating layer 110. The first insulating layer 110 may include an insulating material such as oxide (e.g., SiO₂). The first interconnection structures 120 may include metal, such as copper or aluminum. Each of the first interconnection structures 120 may include first interconnection lines 121 stacked in the third direction D3 and first interconnection vias 122 interposed therebetween. A plurality of first interconnection lines 121 may be configured to route signals.

The second interconnection layer 200 may be disposed on the back side of the integrated circuit layer ICL. The second interconnection layer 200 may include a second insulating layer 210, second interconnection structures 220, and dummy metal structures 230.

The second interconnection layer 200 may include a first region A1 and a second region A2 that are alternately and repeatedly arranged. The first region A1 is where the second interconnection structures 220 are provided, while the second region A2 is where the dummy metal structures 230 are disposed. Alternatively, the first region A1 may be a portion of the second interconnection layer 200 that overlaps with a connection terminal 260 in the third direction D3, and the second region A2 may be another portion of the second interconnection layer 200 that does not overlap with the connection terminal 260 in the third direction D3.

The second insulating layer 210 may include a plurality of lower insulating layers. Each of the lower insulating layers may include at least one of silicon oxide, silicon nitride, and silicon oxynitride, and may include an inorganic insulating material.

The second interconnection structures 220 may include a plurality of second interconnection lines 221 stacked in the third direction D3, and second interconnection vias 222 disposed therebetween. Referring to FIG. 3, each of the second interconnection lines 221 may include a first extension 2211 extending in the first direction D1, or a second extension 2212 extending in the second direction D2. In some cases, the second extension 2212 may connect two first extensions 2211 to each other. The interconnection vias 222 may be disposed on one or both ends of the second interconnection line 221. Most of the second interconnection structure 220 may function as a power rail that transmits power and form a power distribution network.

The dummy metal structure 230 may be spaced apart from the interconnection structures 220 in the first direction D1. The dummy metal structure 230 may not be electrically connected to the interconnection structure 220. The dummy metal structure 230 may include a mesh pattern 231 and dummy vias 232 connecting the mesh pattern 231 to each other. As shown in FIG. 3, the mesh pattern 231 may include a plurality of first dummy lines 2311 and second dummy lines 2312 forming a grid shape. The first dummy lines 2311 may be spaced apart from each other in the second direction D2 and extend in the first direction D1. The second dummy lines 2312 may be spaced apart from each other in the first direction D1 and extend in the second direction D2. The first dummy lines 2311 and the second dummy lines 2312 may intersect each other. The dummy vias 232 may be disposed on the first dummy lines 2311, the second dummy lines 2312, or at their intersection points.

The second interconnection structures 220 and the dummy metal structures 230 may include metal, such as copper or aluminum. The second interconnection line 221 may include the same metal material as the mesh pattern 231 adjacent thereto in the first direction D1. The second interconnection via 222 may include the same metal material as the dummy via 232 adjacent thereto in the first direction D1.

The number of stacked mesh patterns 231 may be equal to the number of stacked second interconnection lines 221. The number of dummy vias 232 may be greater than the number of second interconnection vias 222. For example, the number of dummy vias 232 in contact with one mesh pattern 231 may be greater than the number of second interconnection vias 222 in contact with one second interconnection line 221.

According to some embodiments, a height 222H of the second interconnection via 222 and a height 232H of the dummy via 232 may be substantially the same. The height 222H of the second interconnection via 222 may correspond to the separation distance between the second interconnection lines 2221 adjacent to each other in the third direction D3. The height 232H of the dummy via 232 may correspond to the separation distance between the mesh patterns 231 adjacent to each other in the third direction D3.

Some of the second interconnection structures 220 may function as signal lines. These signal lines may not be in contact with other second interconnection structures 220 and may not be connected to each other within the second interconnection layer 200. Previously, a first signal contact SC1 may have been provided, protruding from the first interconnection structure 120 toward the integrated circuit layer ICL. A second signal contact SC2, connected to the first signal contact SC1, may be provided from some of the second interconnection structures 220 constituting the signal line. At least one of the first signal contact SC1 and the second signal contact SC2 may penetrate the integrated circuit layer ICL. The first signal contact SC1 and the second signal contact SC2 may be connected to each other. According to some embodiments, the first signal contact SC1 and the second signal contact SC2 may be in direct contact. Both of the first signal contact SC1 and the second signal contact SC2 may be electrically connected to the gate contact CB described above.

The second insulating layer 210 may fill spaces between the second interconnection structure 220 and the dummy metal structure 230, spaces between the stacked second interconnection lines 221, spaces between the stacked mesh patterns 231, the intersections of the first dummy lines 2311 and the second dummy lines 2312. The second insulating layer 210 may include a first recess R1 and a second recess R2 at a lower portion thereof. The first recess R1 may be disposed in the first region A1 of the second interconnection layer 200, and the second recess R2 may be disposed in the second region A2 of the second interconnection layer 200. The first recess R1 may overlap with the second interconnection structure 220 in the third direction D3. The second recess R2 may overlap with the dummy metal structure 230 in the third direction D3. The first recess R1 may expose a lower surface of the lowermost second interconnection line 221M among the stacked second interconnection lines 221. The lowermost second interconnection line 221M may include a pad (e.g., aluminum pad). An under bump pattern 250 may be provided in the first recess R1. The under bump pattern 250 may fill at least a portion of the first recess R1. The under bump pattern 250 may extend onto the lower surface of the second insulating layer 210. The under bump pattern 250 may be electrically connected to the second interconnection structure 220 through the pad, and may not be electrically connected to the dummy metal structure 230. The under bump pattern 250 may include a metal material such as titanium, nickel, copper, etc. The connection terminal 260 may be provided on the under bump pattern 250. The connection terminal 260 may include a conductive material such as solder containing tin, silver, etc. The connection terminal 260 may have a shape such as a pillar or a bump. The second recess R2 may not expose the lowermost mesh pattern 231M among the mesh patterns 231. A depth X2 of the second recess R2 may be smaller than a depth X1 of the first recess R1. The depth X2 of the second recess R2 and the depth X1 of the first recess R1 may be measured in the third direction D3. An insulating pattern 240 may be provided in the second recess R2. The insulating pattern 240 may fill at least a portion of the second recess R2. The insulating pattern 240 may include an insulating material different from that of the second insulating layer 210. Both the insulating pattern 240 and the second insulating layer 210 may include a low dielectric material. The insulating pattern 240 may include a material that has greater thermal conductivity than the second insulating layer 210. For example, the second insulating material may include a carbon-containing polymer, aluminum oxide (Al₂O₃), boron nitride (BN), or an epoxy polymer compound. According to some embodiments, the insulating pattern 240 may extend onto the lower surface of the second insulating layer 210. The support substrate 400 may be disposed on the first interconnection layer 100. The support substrate 400 may be, for example, a silicon substrate. The adhesive layer 410 may be provided between the support substrate 400 and the first interconnection layer 100. For example, the adhesive layer 410 may include a material such as silicon oxide or silicon nitride.

According to an embodiment of the inventive concept, the semiconductor device 1000 may be electrically insulated from the power rail and signal line of the second interconnection structure 220 on the back surface of the integrated circuit layer ICL, and may include the dummy metal structure 230 disposed adjacent thereto. The dummy metal structure 230 may serve as a heat sink, dissipating heat generated by the second interconnection structure 220 during the operation of the semiconductor device 1000. When the second interconnection structure 220 and the dummy metal structure 230 are electrically connected, the dummy metal structure 230 may also serve as a path for electrical flow, thereby increasing overall resistance. In addition, the second interconnection structure 220 may be electrically connected to the integrated circuit layer ICL, and charge generated by plasma generated during the manufacturing process may be transferred to the integrated circuit layer ICL, reducing the reliability of the semiconductor device 1000. In contrast, according to an embodiment of the inventive concept, the second interconnection structure 220 may be electrically insulated from the dummy metal structure 230, thereby reducing damage caused by plasma. Furthermore, the insulating pattern 240 disposed adjacent to the dummy metal structure 230 may include a material with high thermal conductivity, maximizing the heat dissipation effect.

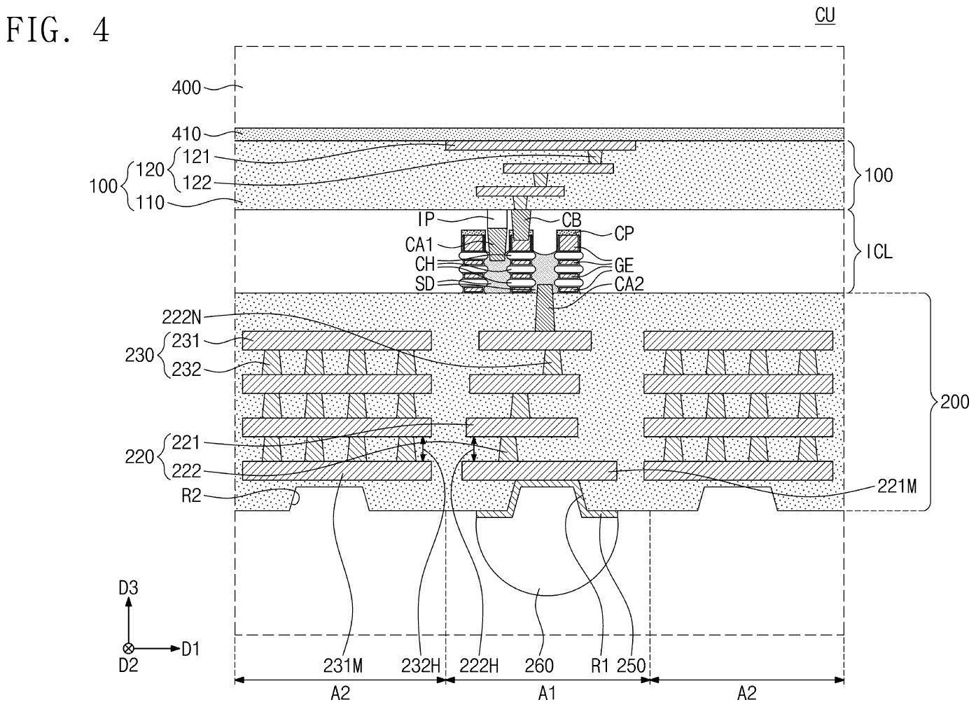

FIGS. 4, 5, and 6 are diagrams showing semiconductor devices according to some embodiments, and correspond to an enlarged view of area CU in FIG. 2. Except for what is explained below, since it is the same as what was explained through FIGS. 1 to 3, overlapping descriptions will be omitted.

Referring to FIG. 4, a semiconductor device according to some embodiments may not include an insulating pattern 240. In other words, the insulating pattern 240 may not fill the second recess R2.

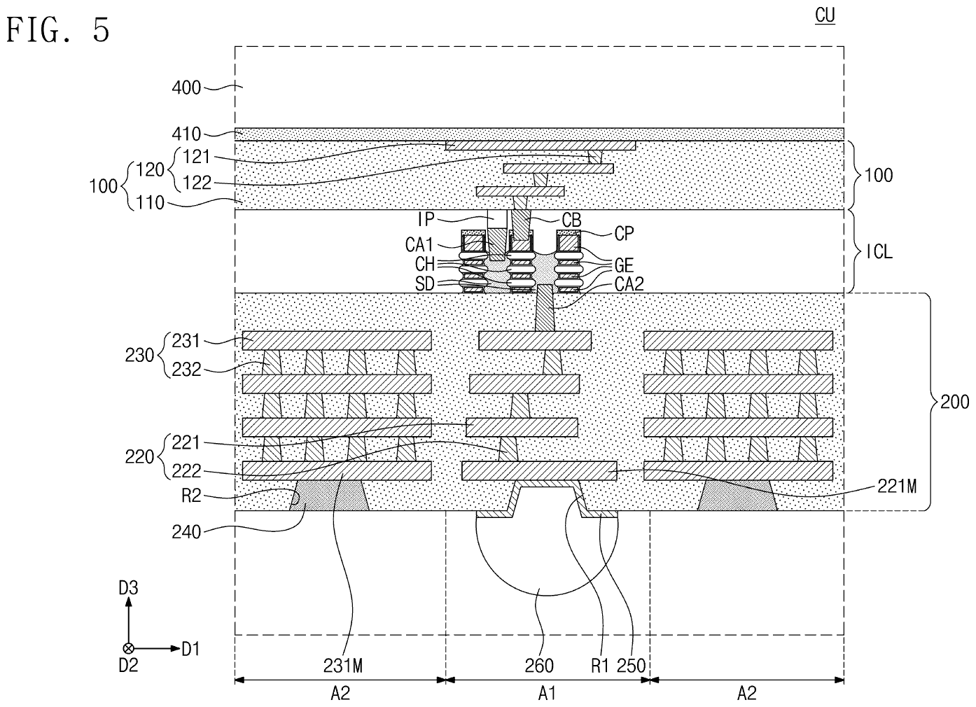

Referring to FIG. 5, according to some embodiments, the second recess R2 may expose the lowermost mesh pattern 231M. A depth of the second recess R2 may be substantially the same as a depth of the first recess R1. The insulating pattern 240 may be in direct contact with the lowermost mesh pattern 231M.

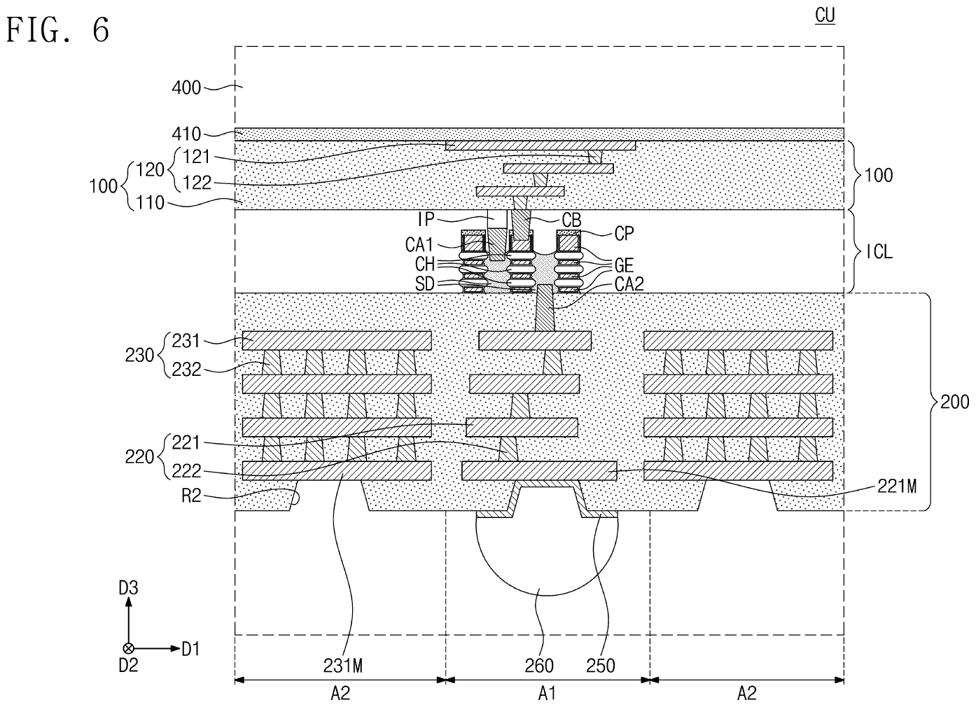

Referring to FIG. 6, a semiconductor device according to some embodiments may not include an insulating pattern 240. The second recess R2 may expose the lowermost mesh pattern 231M, and a depth of the second recess R2 may be substantially the same as a depth of the first recess R1.

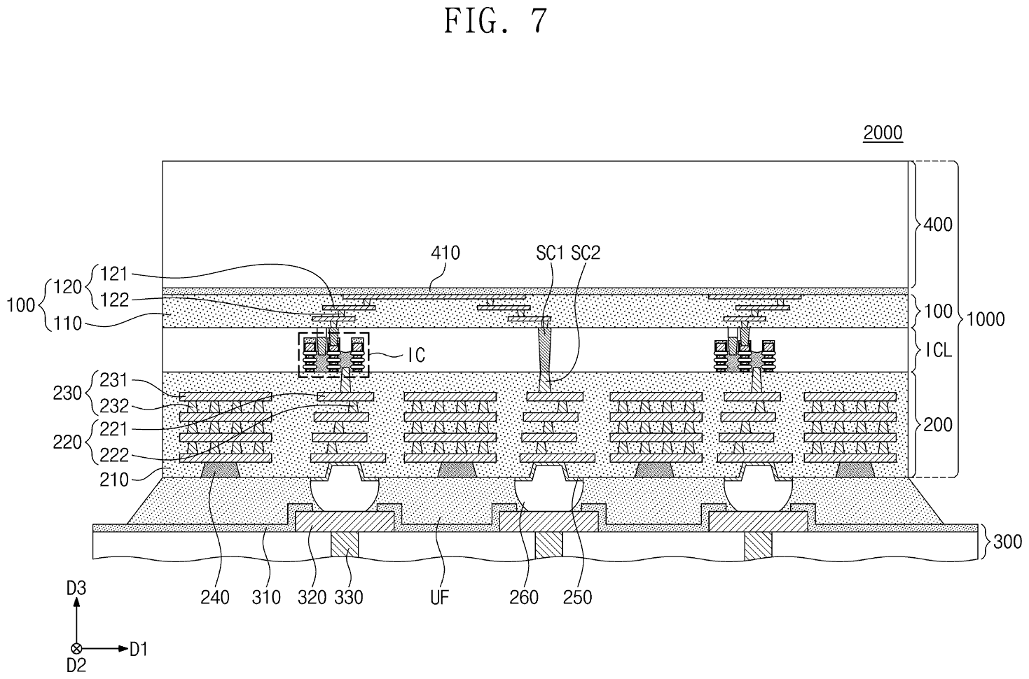

FIG. 7 is a cross-sectional view of a semiconductor package including a semiconductor device according to some embodiments of the inventive concept.

Referring to FIG. 7, a semiconductor package 2000 may include a semiconductor device 1000 and a package substrate 300 disposed below the semiconductor device 1000. The package substrate 300 may be one of the following: an interposer substrate, a printed circuit board, a redistribution substrate, or another semiconductor device. When the package substrate 300 is a semiconductor device, the semiconductor device 1000 positioned on top may be referred to as a first semiconductor device 1000, and the semiconductor device 300 located at the bottom may be referred to as a second semiconductor device 300. A plurality of connection pads 320 may be provided on the package substrate 300, each in contact with the connection terminals 260. The plurality of connection pads 320 may be electrically connected to the semiconductor device 1000 through the connection terminals 260. The connection pads 320 may be connected to vias 330 disposed below them. A solder resist layer 310 may be provided on an upper surface of the package substrate 300, exposing at least a portion of an upper surface of the connection pads 320. An underfill layer UF may be provided between the package substrate 300 and the semiconductor device 1000. The underfill layer UF may be in contact with the insulating layer 210 and the insulating pattern 240. The underfill layer UF may fill a space between the connection terminals 260. The underfill layer UF may include an epoxy compound. According to some embodiments, the insulating pattern 240 may be omitted and the second recess R2 may not be filled (refer to FIGS. 4 and 6). The underfill layer UF may fill the second recess R2 and be spaced apart from the dummy metal structure 230. According to some embodiments, the underfill layer UF may fill the second recess R2 and may be in contact with the dummy metal structure 230 (refer to FIG. 6).

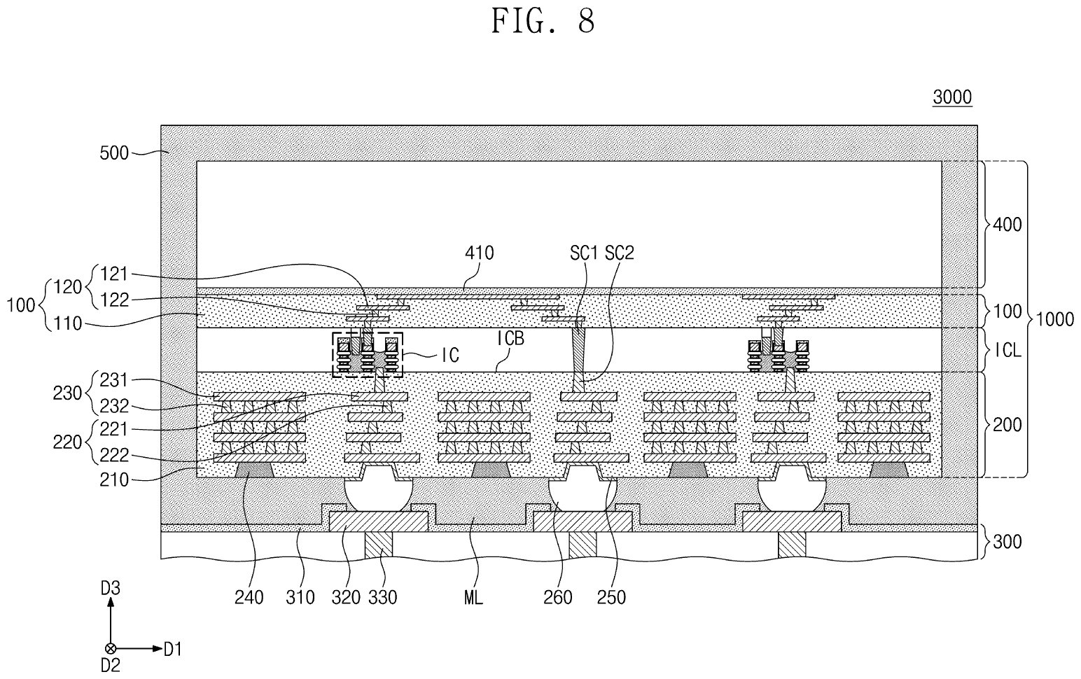

FIG. 8 is a cross-sectional view of a semiconductor package including a semiconductor device according to some embodiments of the inventive concept. Except for those described below, since it is the same as that described in FIG. 7, overlapping descriptions will be omitted. Referring to FIG. 8, a semiconductor package 3000 may further include a molding structure 500. The underfill layer UF between the semiconductor device 1000 and the package substrate 300 may be omitted. The molding structure 500 may cover an upper surface and side surfaces of the semiconductor device 1000 and an upper surface of the package substrate 300. The molding structure 500 may extend between the semiconductor device 1000 and the package substrate 300 and may be in contact with a lower surface of the insulating layer 210 and the insulating pattern 240. The molding structure 500 may fill a space between the connection terminals 260. The molding structure 500 may include an epoxy molding compound. According to some embodiments, the insulating pattern 240 may be omitted and the second recess R2 may not be filled (refer to FIGS. 4 and 6). The molding structure 500 may fill the second recess R2 and be spaced apart from the dummy metal structure 230 (refer to FIG. 4). According to some embodiments, the underfill layer UF may fill the second recess R2 and may be in contact with the dummy metal structure 230 (refer to FIG. 6).

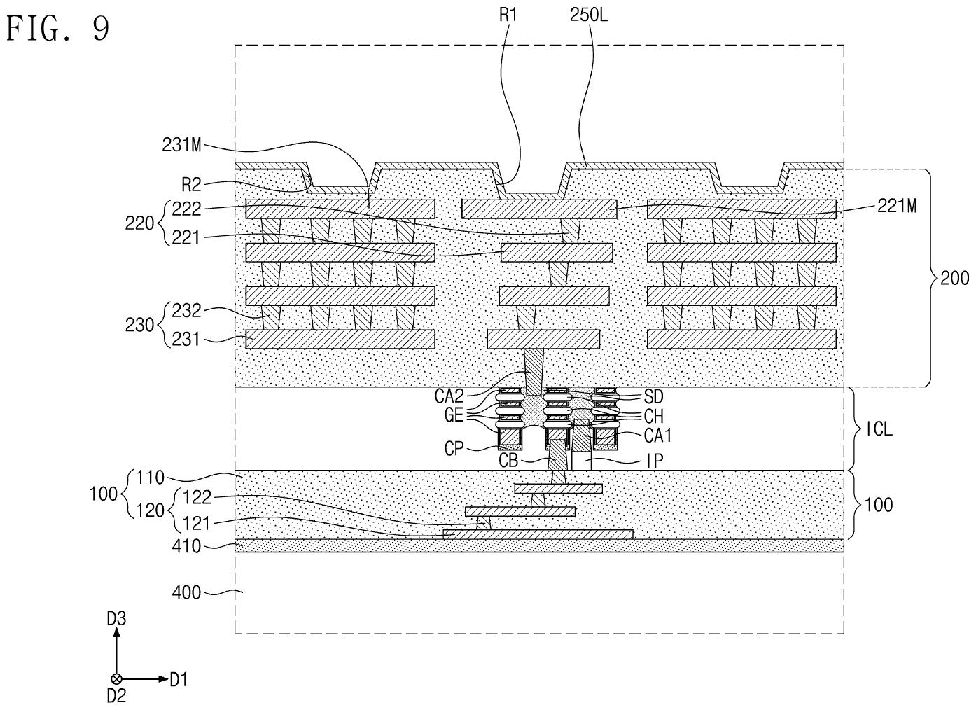

FIGS. 9 to 11 are views showing a process of manufacturing a semiconductor device according to an embodiment of the inventive concept.

Referring to FIG. 9, an integrated circuit IC including a transistor may be formed on a front surface of a semiconductor substrate (e.g., wafer). The transistor may be formed using an MBCFET or GAA forming process. After forming the transistor, a first active contact CA1 connected to a source/drain pattern SD and a gate contact CB connected to a gate GE may be formed. A first interconnection layer 100 may be formed on the front surface of the semiconductor substrate. The first interconnection layer 100 may be bonded to a support substrate 400 through an adhesive layer 410. A process may be performed to reduce the thickness of the back surface of the semiconductor substrate. This reduction in thickness may expose the source/drain pattern SD and form an integrated circuit layer ICL. The integrated circuit layer ICL may be formed by reducing the thickness of the semiconductor substrate on which the integrated circuit IC is formed. A second active contact CA2 may be formed on the source/drain pattern SD. Subsequently, the second interconnection layer 200 may be formed on the integrated circuit IC. Forming the second interconnection layer 200 involves several steps. For example, forming a first lower insulating layer, forming a first metal layer on the first lower insulating layer, and patterning the first metal layer to simultaneously form a second interconnection line 221 and a mesh pattern 231. Subsequently, forming a second lower insulating layer that covers the second interconnection line 221 and the mesh pattern 231, forming an interconnection via hole and a dummy via hole that expose the second interconnection line 221 and the mesh pattern 231 in the second lower insulating layer, forming a second metal layer to fill the interconnection via hole and the dummy via hole, and patterning the second metal layer to simultaneously form a second interconnection via 222 and a dummy via 232. A second interconnection structure 220 may be formed by repeating the formation of the second interconnection line 221 and the second interconnection via 222. A dummy metal structure 230 may be formed by repeating the formation of the mesh pattern 231 and the dummy vias 232. A second insulating layer 210 may be formed by repeating the formation of the lower insulating layer, with a third lower insulating layer formed on the uppermost second interconnection line 221M and the uppermost mesh pattern 231M. The uppermost second interconnection line 221M may include a pad (e.g., aluminum pad). Thereafter, a first recess R1 and a second recess R2 may be formed on the second insulating layer 210. An under bump layer 250L may be formed on an upper surface of the second insulating layer 210, filling portion of both the first recess R1 and the second recess R2. The under bump layer 250L may include at least one of nickel, gold, copper, titanium, and tungsten. The under bump layer 250L may be composed of a single layer or multiple layers.

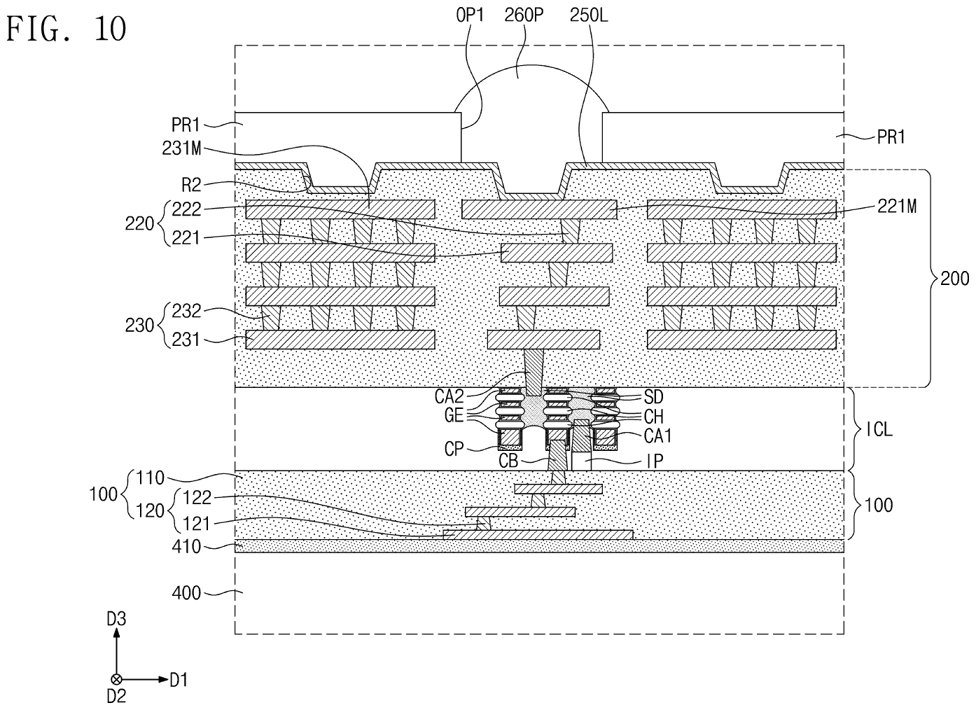

Referring to FIG. 10, a first photomask pattern PRI including a first opening OP1 exposing the first recess R1 may be formed on the under bump layer 250L. The first photomask pattern PR1 may be formed through an exposure and development process using a photoresist material. The first photomask pattern PRI may fill the second recess R2. Using the under bump layer 250L as an electrode, a preliminary connection terminal 260P may be formed through an electroplating process. The under bump layer 250L may serve as a seed layer for this electroplating process.

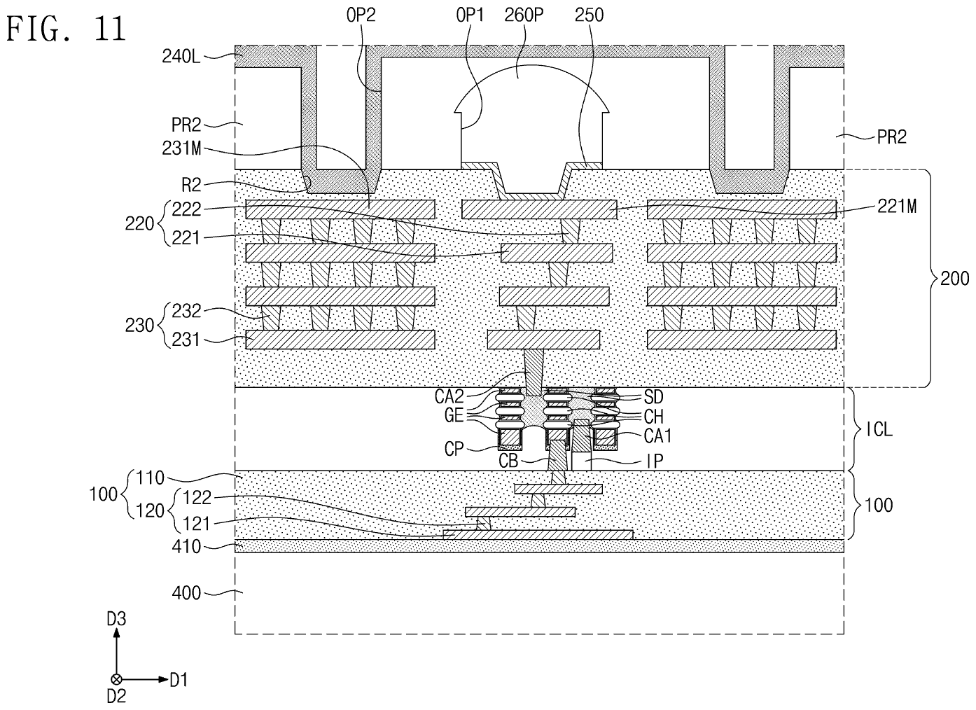

Referring to FIG. 11, the first photomask pattern PR1 may be removed. The under bump layer 250L in the portion that does not overlap the preliminary connection terminal 260P in the third direction D3 may be removed using the preliminary connection terminal 260P as an etch mask. This process patterns the under bump layer 250L to form the under bump pattern 250. Then, a second photomask pattern PR2, which covers upper surfaces of the preliminary connection terminal 260P and the second insulating layer 210 and includes a second opening OP2 exposing the second recess R2, may be formed. A heat transfer insulating layer 240L may then be formed to fill the second recess R2. Depending on the material used (e.g., alumina), the heat transfer insulating layer 240L may then be formed through a deposition process such as a chemical vapor deposition process. Alternatively, if the heat transfer insulating layer 240L includes an insulating material such as a spin on hard mask, the heat transfer insulating layer 240L may be formed by coating and rotating the insulating material.

Referring again to FIGS. 1 and 2, the second photomask pattern PR2 may be removed. For example, other portions of the heat transfer insulating layer 240L covering the second photomask pattern PR2 may be removed by lift off, except for the portion of the heat transfer insulating layer 240L that fills the second recess R2. The heat transfer insulating layer 240L filling the second recess R2 remains to form an insulating pattern 240. A connection terminal 260 may be formed from the preliminary connection terminal 260P by performing a reflow process. According to some embodiments, the reflow process may be performed after forming the under bump pattern 250 and before forming the second photomask pattern PR2. Additionally, the semiconductor device 1000 may be finalized through a sawing process.

According to an embodiment of the inventive concept, the semiconductor device may include the dummy metal structure disposed adjacent to, but electrically insulated from, the power rail and signal line of the back side of the integrated circuit layer. Additionally, the insulating pattern disposed adjacent to the dummy metal structure and exposed to the outside may include a material with high thermal conductivity. The combination of the dummy metal structure and the insulating pattern may enhance the heat dissipation effect of the semiconductor device.

While embodiments are described above, a person skilled in the art will understand that many modifications and variations can be made without departing from the spirit and scope of the inventive concept set forth in the following claims. Accordingly, the embodiments of the inventive concept should be considered illustrative and not restrictive, with the spirit and scope of the inventive concept being indicated by the appended claims.

What is claimed is:

1. A semiconductor device comprising:
an integrated circuit layer including a transistor;
a first interconnection layer on a front side of the integrated circuit layer;
a second interconnection layer on a back side of the integrated circuit layer; and
a connection terminal on the second interconnection layer,
wherein the second interconnection layer includes:
an insulating layer;
an interconnection structure in the insulating layer;
an active contact disposed between the interconnection structure and a source/drain region of the transistor and connected to the source/drain region; and
a dummy metal structure spaced apart from the interconnection structure in a first direction, and
wherein the dummy metal structure does not overlap the connection terminal in a second direction that is perpendicular to the first direction.

2. The semiconductor device of claim 1, wherein the interconnection structure includes an interconnection line and at least one interconnection via connected to the interconnection line, and
wherein the dummy metal structure includes a mesh pattern and a plurality of dummy vias connected to the mesh pattern.

3. The semiconductor device of claim 2, wherein the number of dummy vias in direct contact with one of the mesh patterns is greater than the number of vias in direct contact with one of the interconnection lines.

4. The semiconductor device of claim 1, wherein the dummy metal structure is not electrically connected to the interconnection structure.

5. The semiconductor device of claim 1, wherein the interconnection structure includes a plurality of stacked interconnection lines,
wherein the dummy metal structure includes a plurality of stacked mesh patterns, and
wherein the number of stacked interconnection lines is the same as the number of stacked mesh patterns.

6. The semiconductor device of claim 5, wherein the interconnection lines are positioned at substantially the same level as the mesh patterns adjacent to each other in the first direction.

7. The semiconductor device of claim 1, wherein the insulating layer includes a first recess disposed below the interconnection structure and a second recess spaced apart from the first recess in the first direction and overlapping the dummy metal structure in the second direction,
wherein the semiconductor device further includes:
an under bump pattern disposed in the first recess and interposed between the connection terminal and the interconnection structure; and
an insulating pattern disposed in the second recess, and
wherein the insulating pattern includes an insulating material different from the insulating layer.

8. The semiconductor device of claim 7, wherein the insulating pattern includes (Al₂O₃), bismuth oxide (Bi₂O₃), silicon carbide (SiC), boron nitride (BN), carbon (C), or epoxy polymer compound.

9. The semiconductor device of claim 7, wherein a depth of the first recess is greater than or equal to a depth of the second recess.

10. The semiconductor device of claim 7, wherein the second recess exposes the dummy metal structure.

11. The semiconductor device of claim 7, wherein the second recess is spaced apart from the dummy metal structure, wherein the dummy metal structure overlaps the second recess in the second direction.

12. The semiconductor device of claim 1, further comprising:
a first signal contact extending in the second direction from the first interconnection layer toward the integrated circuit layer; and
a second signal contact extending in the second direction from the second interconnection layer toward the integrated circuit layer,
wherein the first signal contact and the second signal contact are in contact with each other.

13. A semiconductor package comprising:
a package substrate; and
a first semiconductor device on the package substrate,
wherein the first semiconductor device includes:
an integrated circuit layer including a transistor;
a first interconnection layer on a front side of the integrated circuit layer;
a second interconnection layer on a back side of the integrated circuit layer; and
a connection terminal on the second interconnection layer,
wherein the second interconnection layer includes:
an insulating layer;
an interconnection structure in the insulating layer;
an active contact disposed between the interconnection structure and a source/drain region of the transistor and connected to the source/drain region; and
a dummy metal structure spaced apart from the interconnection structure in a first direction, and
wherein the dummy metal structure has a mesh shape when viewed in a plan view.

14. The semiconductor package of claim 13, wherein the package substrate includes an interposer, a printed circuit board, or a redistribution substrate.

15. The semiconductor package of claim 14, wherein the insulating layer includes a first recess disposed below the interconnection structure and a second recess spaced apart from the first recess in the first direction,
wherein the second recess vertically overlaps the dummy metal structure, and
wherein the semiconductor package further includes an under bump pattern disposed in the first recess and interposed between the connection terminal and the interconnection structure.

16. The semiconductor package of claim 15, further comprising an underfill layer disposed between the package substrate and the first semiconductor device,
wherein the underfill layer fills the second recess.

17. The semiconductor package of claim 15, further comprising a molding structure covering an upper surface of the package substrate and side and upper surfaces of the first semiconductor device,
wherein the molding structure fills a space between the package substrate and the first semiconductor device, and fills the second recess.

18. The semiconductor package of claim 13, wherein the mesh shape includes:
at least two first dummy lines extending in the first direction,
at least two second dummy lines extending in a second direction perpendicular to the first direction intersecting each other.

19. The semiconductor package of claim 15, further comprising an insulating pattern filling the second recess,
wherein the insulating pattern includes alumina (Al₂O₃), bismuth oxide (Bi₂O₃), silicon carbide (SiC), boron nitride (BN), carbon (C), or epoxy polymer compound.

20. A semiconductor device comprising:
an integrated circuit layer including a transistor;
a first interconnection layer on a front side of the integrated circuit layer;
a second interconnection layer on a back side of the integrated circuit layer; and
a connection terminal on the second interconnection layer,
wherein the transistor includes:
stacked channel patterns;
a gate surrounding the channel patterns; and
first and second source/drain regions spaced apart from each other with the channel patterns interposed therebetween,
a first active contact protruding from the first interconnection layer and connected to the first source/drain region; and
a second active contact protruding from the second interconnection layer and connected to the second source/drain region,
wherein the second interconnection layer includes:
an insulating layer including a first recess and a second recess at the bottom of the second interconnection layer;
an interconnection structure in the insulating layer; and
a dummy metal structure disposed in the insulating layer and spaced apart from the interconnection structure;
an under bump pattern that fills the first recess and is disposed between the connection terminal and the insulating layer; and
an insulating pattern that fills the second recess and is spaced apart from the under bump pattern in a first direction, and
wherein the insulating layer and the insulating pattern include different insulating materials.
